(19) United States
(12) Patent Application Publication
(10) Pub. No.: US 2015/0177290 A1
(43) Pub. Date: Jun. 25, 2015

(54) CONTROLLER FOR AUTOMATICALLY DETECTING THE MAXIMAL OPERATING CURRENT OF LIGHT SOURCES AND DETECTION METHOD THEREOF

(71) Applicant: DONGGUAN OPT MACHINE VISION TECH CO., LTD., Dongguan City (CN)

(72) Inventor: Shenglin LU, Dongguan City (CN)

(73) Assignee: DONGGUAN OPT MACHINE VISION TECH CO., LTD., Dongguan City (CN)

(21) Appl. No.: 14/287,364

(22) Filed: May 27, 2014

(30) Foreign Application Priority Data
Dec. 23, 2013 (CN) 201310715623.2

(51) Int. Cl. G01R 19/30; G01R 31/44

(52) U.S. Cl. CPC G01R 19/30; G01R 31/44

(57) ABSTRACT

The present invention relates to the technical field of a light source detection apparatus, in particular to a controller for automatically detecting the maximum operating current of a light source and detection method thereof. The controller comprises a master control module, a constant current output module and a load detection module. The control signal output end of the master control module is electrically connected to the control signal input end of the constant current output module; the constant current output module, according to the control signal of the master control module, outputs a corresponding constant current; the signal output end of the load detection module is electrically connected to the signal input end of the master control module, while the current output end of the constant current output module is electrically connected to the detection input end of the load detection module.

### FIELD OF THE INVENTION

The present invention relates to the technical field of a light source detection apparatus, in particular to a controller for automatically detecting the maximum operating current of a light source and detection method thereof.

### BACKGROUND OF THE INVENTION

At present, electrical energy light sources have been widely used in varieties of fields no matter in the field of general lighting or the field of signal indication. According to its power supply, the existing light sources may include constant-voltage drive power supplies and constant-current drive power supplies, which have been commonly used in practical applications. In the case where a constant-voltage drive power is applied, the current will fluctuate as components heat and resistances increase or decrease when the light source operates over time, causing instability and seriously affecting the service life of lamps. In the case where a constant-current drive power supply is applied, the current will not change, which is better for the service life and stability of the whole lamps.

However, generally only the rated voltage is marked on an existing light source, while the supply current of the light source is not clear yet. At present, with respect to some drive power supplies using a constant-current drive power supply as the light source, it is difficult to know how much output current is required to supply power to the light source if the maximum operating current is not clear. It is difficult for the light source to play high efficiency if the drive current is too low; and the service life of the light source will be seriously affected if the drive current is too high, discarding the light source in advance.

The maximum operating current of a light source is the current at which the light source operates at the rated voltage. For a light source with adjustable brightness, the output current of the drive power supply thereof cannot be greater than the maximum operating current. On an occasion where the brightness of a light source is to be adjusted, the adjustment range of the brightness of the light source will be influenced if the maximum operating current of the light source is not clear. Any carelessness may cause the current too high thus to damage the light source, of which an existing controller cannot be aware. As the current is being changing when the operating voltage of the light source is constant, it is difficult to detect the maximum operating current. The existing controllers are obviously disadvantageous.

### SUMMARY OF THE INVENTION

The technical problem to be solved in the present invention is to provide a controller for automatically detecting the maximum operating current of a light source with simple structure, fast speed and high accuracy, as well as a detection method thereof.

In order to solve the technical problem described above, the present invention employs the following technical solution: a controller for automatically detecting the maximum operating current of a light source is provided, including a master control module, a constant current output module and a load detection module. The control signal output end of the master control module is electrically connected to the control signal input end of the constant current output module; the constant current output module, according to the control signal of the master control module, outputs a corresponding constant current; and the signal output end of the load detection module is electrically connected to the signal input end of the master control module, while the current output end of the constant current output module is electrically connected to the detection input end of the load detection module.

The present invention further provides the detection method by using the controller for automatically detecting the maximum operating current of a light source includes the following steps:

1) the electric energy input end of the light source to be detected is electrically connected to the current output end of the constant current output module;

2) the master control module sends, to the constant current output module, a control signal of gradually increasing the output current; and meanwhile the load detection module feeds the detected voltage signal back to the master control module in real-time; and

3) the master control module sends a control signal to the constant current output module when the feedback voltage signal value received by the master control module reaches a rated voltage value of the light source to be detected, to stop the constant current output module from increasing the output current; the present current value output by the constant current output module is the maximum current value of the light source to be detected.

In addition, in order to solve the technical problem described above, the present invention may further employ another technical solution: a controller for automatically detecting the maximum operating current of a light source is provided, including a master control module, a constant current output module, a current detection module and a load rated voltage output module. The first control signal output end of the master control module is electrically connected to the control signal input end of the constant current output module, while the circuit output end of the constant current output module is connected with a detection connection end; and the second control signal output end of the master control module is electrically connected to the control signal input end of the load rated voltage output module, and the voltage output end of the load rated voltage output module is connected in series to the current detection module and the detection connection end.

The present invention further provides a detection method by using the controller for automatically detecting the maximum operating current of a light source, including the following steps:

1) the master control module sends a control signal to the load rated voltage output module and the constant current output module, respectively, to regulate the output voltage of the load rated voltage output module to zero and regulate the output current of the constant current output module to zero;

2) the electric energy input end of the light source to be detected is electrically connected to the detection connection end; and

3) the master control module sends, to the load rated voltage output module, a control signal of regulating the output voltage to the rated voltage of the light source to be detected; and meanwhile the current detection module feeds the detected current signal back to the master control module, and the master control module records the current value at this moment as the maximum current value of the light source to be detected.

The present invention has the following beneficial effects: a controller for automatically detecting the maximum operating current of a light source is provided, after connected to the light source, the controller applies a rated voltage to a light source loop and detects the current value of the light source loop, and sets the maximum output current of the light source loop on the basis of the current value. The light source detection apparatus has the advantages of fast speed, high accuracy and high practicality.

### BRIEF DESCRIPTION OF THE DRAWINGS

FIG. 1 is a schematic circuit block diagram of a controller for automatically detecting the maximum operating current of a light source according to a first embodiment of the present invention; and

FIG. 2 is a schematic circuit block diagram of a controller for automatically detecting the maximum operating current of a light source according to a second embodiment of the present invention.

### DETAILED DESCRIPTION OF THE PREFERRED EMBODIMENTS

In order to be understood easily by those skilled in the art, the present invention will be further described with reference to the drawings by embodiments. The contents mentioned in the implementations are not intended to form any limitation to the present invention.

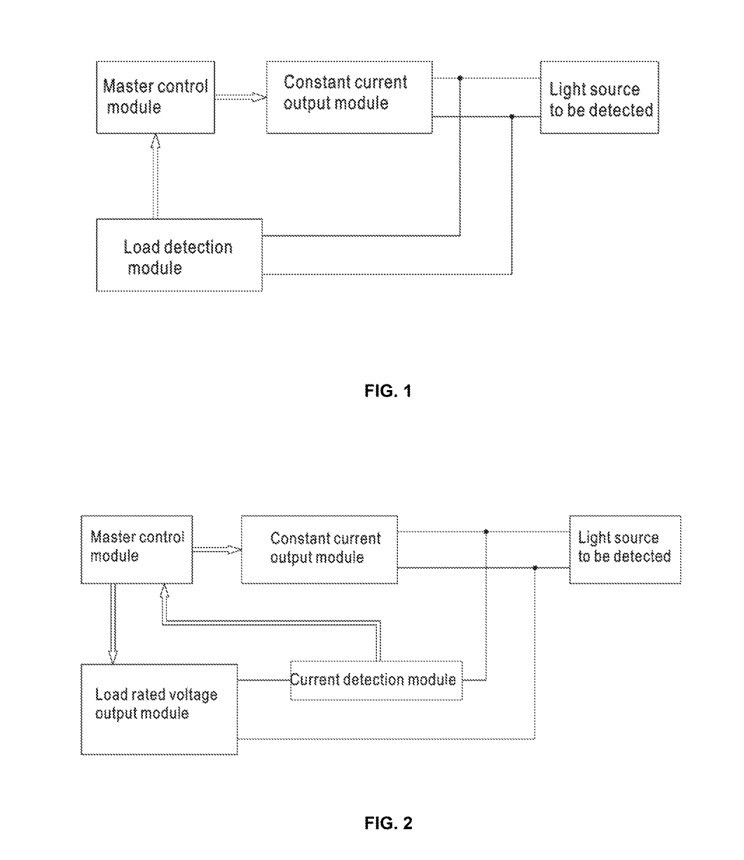

As illustrated in the FIG. 1, a controller for automatically detecting the maximum operating current of a light source according to a first embodiment of the present invention is shown, including a master control module, a constant current output module and a load detection module. The control signal output end of the master control module is electrically connected to the control signal input end of the constant current output module; the constant current output module, according to the control signal of the master control module, outputs a corresponding constant current; the signal output end of the load detection module is electrically connected to the signal input end of the master control module, while the current output end of the constant current output module is electrically connected to the detection input end of the load detection module.

In the practical applications, the detection method by using the controller for automatically detecting the maximum operating current of a light source includes the following steps:

1) the electric energy input end of the light source to be detected is electrically connected to the current output end of the constant current output module;

2) the master control module sends, to the constant current output module, a control signal of gradually increasing the output current; and meanwhile the load detection module feeds the detected voltage signal back to the master control module in real-time;

3) the master control module sends a control signal to the constant current output module when the feedback voltage signal value received by the master control module reaches a rated voltage value of the light source to be detected, to stop the constant current output module from increasing the output current; the present current value output by the constant current output module is the maximum current value of the light source to be detected.

At this moment, the present current value of the constant current output module is the maximum operating current value of a light source to be detected. The detection step ends. When the constant current output module of the controller continuously supplies power to the light source, the maximum supply current at which the brightness of the light source is adjusted should not be greater than the maximum operating current value, in order to avoid burning the light source or affecting the service life thereof due to overload for a long period of time.

As illustrated in FIG. 2, a controller for automatically detecting the maximum operating current of a light source according to a second embodiment of the present invention is provided, including: a master control module, a constant current output module, a current detection module and a load rated voltage output module; the first control signal output end of the master control module is electrically connected to the control signal input end of the constant current output module, while the circuit output end of the constant current output module is connected with a detection connection end; and the second control signal output end of the master control module is electrically connected to the control signal input end of the load rated voltage output module, and the voltage output end of the load rated voltage output module is connected in series to the current detection module and the detection connection end.

In the practical applications, the detection method by using the controller for automatically detecting the maximum operating current of a light source includes the following steps:

1) the master control module sends a control signal to the load rated voltage output module and the constant current output module, respectively, to regulate the output voltage of the load rated voltage output module to zero and regulate the output current of the constant current output module to zero;

2) the electric energy input end of the light source to be detected is electrically connected to the detection connection end;

3) the master control module sends, to the load rated voltage output module, a control signal of regulating the output voltage to the rated voltage of the light source to be detected; and meanwhile the current detection module feeds the detected current signal back to the master control module, and the master control module records the current value at this moment as the maximum current value of the light source to be detected.

At this moment, the present current value output by the constant current output module is the maximum current value of the light source to be detected. The detection step ends. When the constant current output module of the controller continuously supplies power to the light source, the maximum supply current at which the brightness of the light source is adjusted should not be greater than the maximum operating current value, in order to avoid burning the light source or affecting the service life thereof due to overload for a long period of time.

In this embodiment, as the controller performs detection directly from the current value, the detection speed is further improved, and both the detection efficiency and the practicability are higher.

The forgoing embodiments are just preferred implementations of the present invention. The present invention may further have other implementations in addition to these embodiments mentioned above. Any obvious replacements made without departing from the concept of the technical solution shall be included within the protection scope of the present invention.

What is claimed is:

1. A controller for automatically detecting the maximum operating current of a light source, comprising a master control module and a constant current output module, characterized by further comprising a load detection module; the control signal output end of the master control module is electrically connected to the control signal input end of the constant current output module, while the constant current output module, according to the control signal of the master control module, outputs a corresponding constant current; and
the signal output end of the load detection module is electrically connected to the signal input end of the master control module, while the current output end of the constant current output module is electrically connected to detection input end of the load detection module.

2. A detection method by using the controller for automatically detecting the maximum operating current of a light source according to claim 1, comprising the following steps:
1) the electric energy input end of the light source to be detected is electrically connected to the current output end of the constant current output module;
2) the master control module sends, to the constant current output module, a control signal of gradually increasing the output current; and meanwhile the load detection module feeds the detected voltage signal back to the master control module in real-time; and
3) the master control module sends a control signal to the constant current output module when the feedback voltage signal value received by the master control module reaches a rated voltage value of the light source to be detected, to stop the constant current output module from increasing the output current; the present current value output by the constant current output module is the maximum current value of the light source to be detected.

3. A controller for automatically detecting the maximum operating current of a light source, comprising a master control module and a constant current output module, characterized by comprising a current detection module and a load rated voltage output module; the first control signal output end of the master control module is electrically connected to the control signal input end of the constant current output module, while the circuit output end of the constant current output module is connected with a detection connection end; and
the second control signal output end of the master control module is electrically connected to the control signal input end of the load rated voltage output module, and the voltage output end of the load rated voltage output module is connected in series to the current detection module and the detection connection end.

4. A detection method by using the controller for automatically detecting the maximum operating current of a light source according to claim 3, comprising the following steps:
1) the master control module sends a control signal to the load rated voltage output module and the constant current output module, respectively, to regulate the output voltage of the load rated voltage output module to zero and regulate the output current of the constant current output module to zero;
2) the electric energy input end of the light source to be detected is connected to the detection connection end; and
3) the master control module sends, to the load rated voltage output module, a control signal of regulating the output voltage to the rated voltage of the light source to be detected; and meanwhile the current detection module feeds the detected current signal back to the master control module, and the master control module records the current value at this moment as the maximum current value of the light source to be detected.
